(19) United States
(12) Patent Application Publication
(10) Pub. No.: US 2023/0019747 A1
(43) Pub. Date: Jan. 19, 2023

(54) HYBRID LASER ARCHITECTURE WITH ASYMMETRIC METAL SHUNT

(71) Applicants: Richard Jones, San Mateo, CA (US); Pierre Doussiere, Santa Clara, CA (US); Aditi Mallik, Cupertino, CA (US); Harel Frish, Albuquerque, NM (US); John Heck, Berkeley, CA (US); Saeed Fathololoumi, Los Gatos, CA (US)

(72) Inventors: Richard Jones, San Mateo, CA (US); Pierre Doussiere, Santa Clara, CA (US); Aditi Mallik, Cupertino, CA (US); Harel Frish, Albuquerque, NM (US); John Heck, Berkeley, CA (US); Saeed Fathololoumi, Los Gatos, CA (US)

(21) Appl. No.: 17/952,083

(22) Filed: Sep. 23, 2022

(51) Int. Cl. H01S 5/024; H01S 5/22; H01S 5/02

(52) U.S. Cl. CPC H01S 5/02469; H01S 5/22; H01S 5/0218; H01S 5/323

(57) ABSTRACT

Embodiments herein relate to an apparatus for use in a hybrid laser. The apparatus may include a silicon substrate and a waveguide to facilitate transmission of an optical signal in a first direction that is orthogonal to a surface of the silicon substrate. The apparatus may further include a metal shunt that is less than or equal to 10 micrometers from the waveguide in a second direction that is orthogonal to the surface of the silicon substrate and orthogonal to the first direction. Other embodiments may be described and/or claimed.

### BACKGROUND

Embodiments of the present disclosure generally relate to the field of metal shunts in hybrid lasers. Specifically, legacy hybrid lasers may include a waveguide along which an optical signal may be generated. The generation and transmission of the optical signal may generate heat. In some cases, it may be desirable to dissipate heat from the waveguide and, more generally, the hybrid laser architecture.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 illustrates an example of a hybrid laser architecture with an asymmetric metal shunt, in accordance with various embodiments.

FIG. 2 provides an alternative example of a hybrid laser architecture with an asymmetric metal shunt, in accordance with various embodiments.

FIGS. 3a and 3b depict example thermal contours of symmetric and asymmetric hybrid laser architectures, respectively, in accordance with various embodiments.

FIG. 4 depicts examples of differences in thermal resistance (R_{TH}) in different hybrid laser architectures, in accordance with various embodiments.

FIG. 5 illustrates an example process related to forming a hybrid laser architecture with an asymmetric shunt, in accordance with various embodiments.

FIG. 6 illustrates an example computing system suitable for practicing various aspects of the disclosure, in accordance with various embodiments.

FIG. 7 illustrates an example non-transitory computer-readable storage medium having instructions configured to practice all or selected ones of the operations associated with the processes described in reference to FIGS. 5 and 6, and/or some other method, process, technique, or operation described herein, in whole or in part.

### DETAILED DESCRIPTION

Embodiments described herein may include apparatus, systems, techniques, or processes that are directed to a hybrid laser architecture with an asymmetric shunt, in accordance with various embodiments.

In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. It will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

As used herein, the term “module” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable components that provide the described functionality.

Embodiments herein relate to an architecture for a hybrid laser. In some embodiments, the laser may be referred to as a “III-V” hybrid laser. The III-V hybrid laser may include both silicon and group III-V semiconductor materials such as indium phosphide, gallium arsenide, etc.

As noted previously, such a hybrid laser may include a silicon waveguide which may be used to generate, transmit, or otherwise control an optical signal. The optical signal in the hybrid laser may generate thermal energy (i.e., heat), and so it may be desirable to remove the heat from the hybrid laser.

In legacy packages, thermal shunts may have been placed in a symmetric design orthogonal to the direction of travel of the optical signal. Specifically, the thermal shunts may have been approximately 56 micrometers (“microns” or “μm”) away from the silicon waveguide on opposite sides of the silicon waveguide from one another. The thermal shunts may have been or included a thermally conductive metallic material such as aluminum, which may have drawn the thermal energy from the silicon waveguide so that it may be dissipated from the laser architecture.

Embodiments herein relate to a laser architecture with an asymmetric metal shunt. The asymmetric metal shunt may reduce the R_{TH} value of the laser architecture. Specifically, the asymmetric metal shunt may reduce the R_{TH} value of a III-V Silicon (Si) hybrid laser that is bonded on a semi-insulated substrate (SOI) that includes a buried oxide (BOX) layer. In embodiments, the BOX layer may act as or include a thermal barrier that provides a relatively high thermal resistance. The asymmetric shunt design may allow the heat to pass the barrier of the BOX layer more efficiently than a legacy symmetric shunt design.

As previously noted, legacy hybrid laser architectures may rely on symmetric shunts positioned at either side of the silicon waveguide. However, the use of symmetric shunts may have required the shunts to be placed relatively far away (e.g., on the order of approximately 56 microns) from the silicon waveguide because the hybrid laser may have required n-electrodes to run on either side of the waveguide. The shunts may have had to be placed at the relatively far-away position to allow for placement of the n-electrodes close to the silicon waveguide. As such, the shunts may not have been optimally thermally efficient and had a relatively high R_{TH} value.

Embodiments herein may only rely on a single n-electrode on one side of a silicon waveguide, and a closer metal shunt on the other side of the silicon waveguide (a design referred to herein as an “asymmetric” design). By using the asymmetric design, heat may be more efficiently pulled from the silicon waveguide by the shunt and dissipated into the SOI layer. More specifically, the shunt may be placed approximately five times closer to the silicon waveguide (e.g., approximately 10 microns from the silicon waveguide) than the symmetric shunts of legacy designs. As a result, the R_{TH} value of the asymmetric architecture may be reduced by approximately 18.5%, as opposed to the approximately 5% reduction provided by symmetric shunt designs.

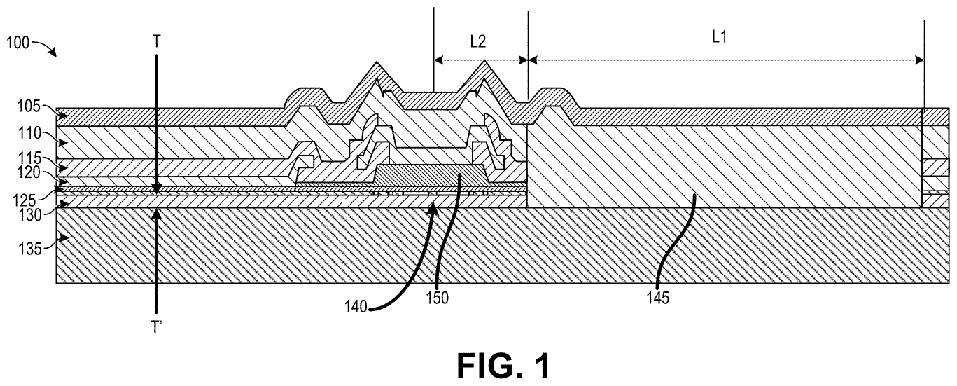

FIG. 1 illustrates an example of a hybrid laser architecture 100 with an asymmetric metal shunt 145, in accordance with various embodiments. Specifically, FIG. 1 depicts a cross-sectional view of such an architecture. In this embodiment, the laser may travel into or out of the Figure. It will be noted that the specific structures of FIG. 1 may be illustrated at a scale that is different than that of a real-world implementation. The scale of FIG. 1 may be for the purpose of illustrating the placement, and facilitating discussion, of the different elements of the architecture 100.

The architecture 100 may include a variety of layers, as shown in FIG. 1. Specifically, the architecture 100 may include a silicon substrate layer 135. In some embodiments, the silicon substrate layer 135 may additionally or alternatively be referred to as a SOI.

A silicon oxide (SiO₂) layer 130 may be deposited on the surface of the silicon substrate layer 130. In some embodiments, the SiO₂ layer 130 may serve as a thermal barrier between structures of the laser and the silicon substrate layer 130.

A silicon waveguide 140 may be placed on the SiO₂ layer 130. The silicon waveguide may serve to direct and focus the optical signal as it propagates through the architecture 100.

The architecture 100 may further include an n-doped III-V electrode 125, an n-metal electrode 120, and a p-metal electrode 110. The n-doped III-V electrode 125 may be or include group III-V materials as described above (e.g., indium phosphide, gallium arsenide, etc.). The metal electrodes 110/120 may be or include a metallic material such as aluminum or some other material. In other embodiments, one or both of the electrodes 110/120 may be or include another material such as copper, tantalum nitride (TaN), etc.

In some embodiments, the electrodes 125 and 120 may be separated from the electrode 110 by a dielectric layer 115. The dielectric layer 115 may be, for example, SiO₂. In other embodiments, the dielectric layer 115 may be, for example silicon nitride or some other appropriate dielectric material.

In addition to the dielectric layer 115, the p-metal electrode 110 may be separated from the n-doped III-V electrode 125 by a mesa 150. The mesa 150 may be formed of a material such as, for example, indium phosphide, gallium arsenide, and/or some other III-V material. The area between the mesa 150 and the silicon substrate 135 may be referred to as the “active area” of the hybrid laser. Specifically, as used herein, the active area of the hybrid laser may refer to an area in which an optical signal (and hence thermal energy) is being generated or manipulated.

A passivation layer 105, which may be a material such as silicon nitride, silicon dioxide, a polymide material, etc., may be placed on the p-metal electrode. The passivation layer 105 may serve as an environmentally protective layer that may protect the architecture 100 from unfavorable environmental factors such as moisture, heat, physical jostling, etc.

Generally, in embodiments, the optical signal may be generated by providing current through the active area of the hybrid laser. Such current may be provided, for example, between the n-metal electrode 120 and the p-metal electrode 110. Such current may generate an optical signal in the waveguide 140. The gratings in the silicon waveguide 140 (e.g., the holes in the waveguide 140 as may be seen in FIG. 1) may act as mirrors to form the laser cavity.

As may be seen in FIG. 1, the architecture 100 may further include a shunt 145. In embodiments, the shunt 145 may be the same material as the metallic material of the p-metal electrode 110. For example, in this embodiment, the shunt 145 is aluminum. In other embodiments, the shunt 145 may be copper and/or some other metal (or alloys thereof). It will be noted that, in some embodiments, the metal shunt 145 may be a different metallic material than the material of the p-metal electrode 110.

The shunt 145 may have a length L1 on the order of approximately 40 microns. In other embodiments, the shunt 145 may have a length L1 that is on the order of between approximately 20 and approximately 60 microns. In some embodiments, the shunt 145 may have a length L1 that is on the order of between approximately 5 and approximately 100 microns. It will be noted that such length L1 may be based on various factors such as the specific materials used in the architecture 100, the energy of the optical output of the architecture 100, etc. Therefore, in other embodiments, the length L1 may be higher or lower than the above-provided values. Generally, it may be desirable for the length L1 to be approximately 2 times the thickness (e.g., as measured in a direction parallel to the T-T′ measurement) of the shunt 145.

Additionally, as may be seen in FIG. 1, the shunt 145 may be a distance L2 from the center of the silicon waveguide 140 (as measured horizontally with respect to the view of FIG. 1). In some embodiments, the distance L2 may be on the order of approximately 10 microns. In other embodiments, the distance L2 may be on the order of between approximately 5 and approximately 20 microns. Similarly to the length L1, the distance L2 may be based on various factors such as the specific materials used in the architecture 100, the energy of the optical output of the architecture 100, etc. Therefore, in other embodiments, the distance L2 may be higher or lower than the above-provided values.

It will be noted that, in embodiments, the shunt 145 may be coupled with the silicon substrate 135 in a cavity of the SiO₂ layer 130. By coupling the shunt 145 with the silicon substrate 135, the shunt 145 may allow for thermal coupling of the shunt 145 and the silicon substrate 135. Because the shunt 145 is the distance L2 from the center of the silicon waveguide 140, the shunt 145 may also be closely thermally coupled with the silicon waveguide 140 and, more generally, the active area of the hybrid laser. Therefore, the shunt 145 may be configured to draw thermal energy from the active area of the hybrid laser and dissipate that thermal energy through the silicon substrate 135.

It will also be noted, as described above, that the architecture 100 is “asymmetric.” That is, as may be seen in FIG. 1, the shunt 145 may only be present on one side of the silicon waveguide 140 (i.e., the right side of FIG. 1). Similarly, the n-metal electrode 120 may only be present on one side of the silicon waveguide 140 (i.e., the left side of FIG. 1). This configuration may be desirable to allow the shunt 145 to be within distance L2 of the silicon waveguide 140. If the electrode structure of the architecture 100 was symmetric (i.e., the architecture 100 had shunts 145 on either side of the active area and electrodes 120 on either side of the active area) it would not be possible to place the shunts 145 within distance L2 of the silicon waveguide 140, and so the thermal benefits offered by the shunt 145 may not be present.

As an additional benefit of the asymmetric architecture, the SiO₂ layer 130 may have a thickness T-T′ of approximately 2 microns. Generally, in symmetric architectures, the thickness T-T′ of the SiO₂ layer may have been approximately 1 micron. However, in embodiments herein, the asymmetric architecture may allow for a thicker SiO₂ layer 130 because the thermal efficiency offered by the closer metal shunt 145 may reduce the thermal profile of the active area of the hybrid laser. As such, the relatively thinner thermally insulating SiO₂ layer 130 may not be necessary for the hybrid laser. The thicker SiO₂ layer 130 may additionally be desirable, as it may improve optical isolation (reduces optical loss to the silicon substrate), and may be more aligned with industry standards, thereby simplifying the cost of complexity of manufacture of the hybrid laser.

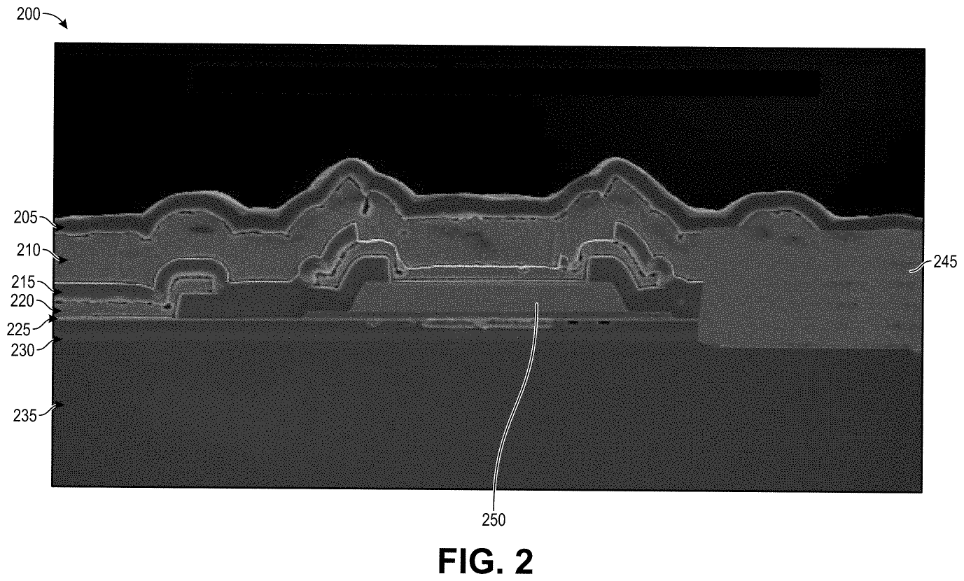

FIG. 2 provides an alternative example of a hybrid laser architecture 200 with an asymmetric metal shunt 245, in accordance with various embodiments. Specifically, FIG. 2 may depict an example of a real-world implementation of such an architecture 200 as may be taken, for example, by a high-powered microscope. The architecture 200 may include a silicon substrate 235, a SiO₂ layer 230, a mesa 250, a dielectric layer 215, a p-metal electrode 210, a passivation layer 205, and a shunt 245, which may be respectively similar to, and share one or more characteristics with, silicon substrate 135, SiO₂ layer 130, mesa 150, dielectric layer 115, p-metal electrode 110, passivation layer 105, and shunt 145. It will be noted that the architecture 200 may include one or more additional elements of FIG. 1, but such elements are not explicitly enumerated in FIG. 2 for the sake of conciseness and lack of redundancy.

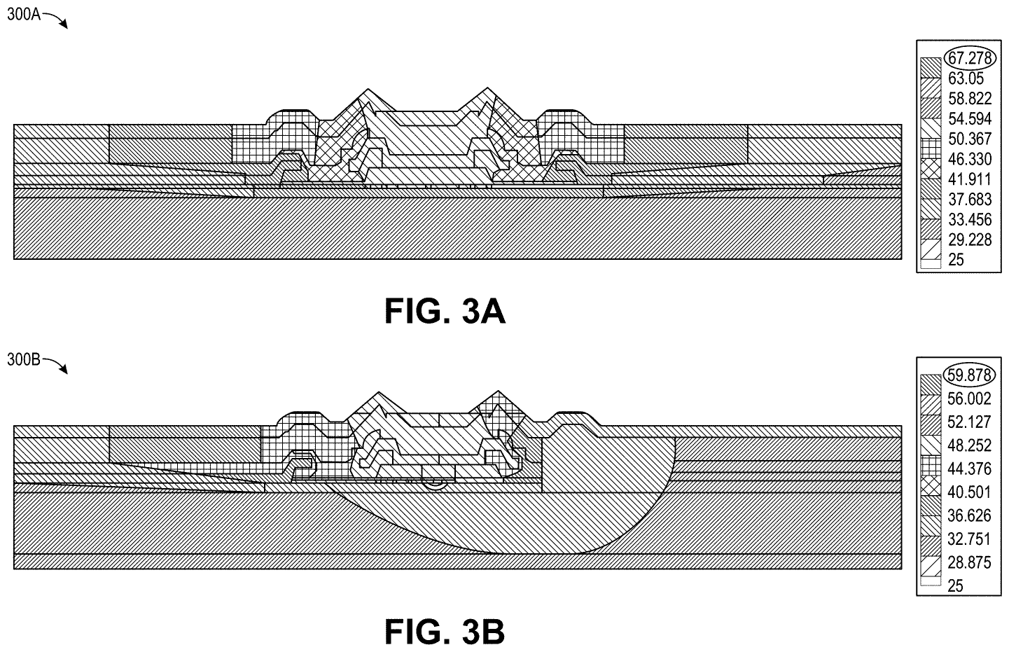

FIGS. 3a and 3b depict example thermal contours 300a and 300b of symmetric and asymmetric hybrid laser architectures, respectively, in accordance with various embodiments. Specifically, FIG. 3a depicts an example thermal contour 300a of a symmetric architecture as described above wherein metal shunts are symmetrically placed approximately 56 microns from the silicon waveguide. By contrast, FIG. 3b depicts an example thermal contour 300b of an asymmetric architecture in accordance with various embodiments herein.

As may be seen by comparison of FIGS. 3a and 3b, the highest temperature of the architecture in the thermal contour 300a of the symmetric architecture may be approximately 67.278 degrees Celsius (° C.). By contrast, the highest temperature of the architecture in the thermal contour 300b of the asymmetric architecture may be approximately 10 degrees cooler (i.e., approximately 59.878° C.) Therefore, it will be noted that the asymmetric shunt architecture may offer significant thermal improvement over the legacy symmetric architecture.

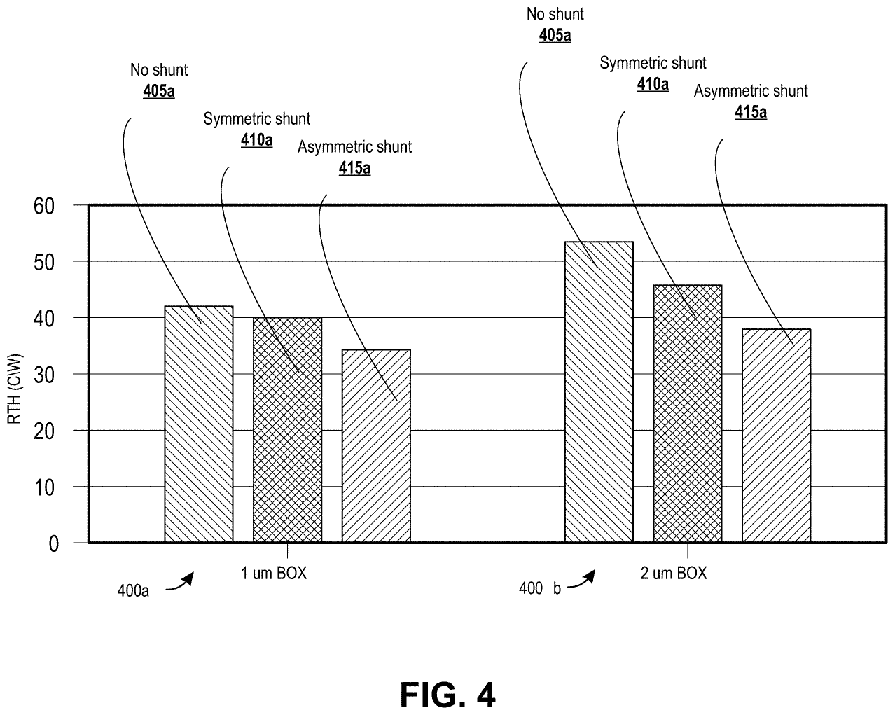

FIG. 4 depicts examples of differences in thermal resistance (R_{TH}) in different hybrid laser architectures, in accordance with various embodiments. It will be understood that a lower R_{TH} value may be desirable, as it may allow for greater thermal dissipation of the laser architecture. The R_{TH} may be measured in units of degrees Celsius per Watt(C/W).

The graph at 400a illustrates relative R_{TH} values for an architecture with a BOX layer (e.g., SiO₂ layer 130/230) with a thickness (e.g., T-T′ value) of approximately 1 micron. As may be seen, the R_{TH} value for an architecture with no shunt at 405a may be a bit over 40 C/W. The R_{TH} value for an architecture with a symmetric shunt 410a may be approximately 40 C/W. The R_{TH} value for an architecture with an asymmetric shunt 415a may be approximately 35 C/W, which may offer an improvement of approximately 12.5% over the symmetric shunt design indicated by 410a.

Similarly, the graph at 400b illustrates relative R_{TH} values for an architecture with a BOX layer with a thickness of approximately 2 microns. As may be seen, the R_{TH} value for an architecture with no shunt at 405b may be approximately 53 C/W. The R_{TH} value for an architecture with a symmetric shunt 410b may be approximately 45 C/W. The R_{TH} value for an architecture with an asymmetric shunt 415b may be approximately 38 C/W, which may offer an improvement of approximately 15.6% over the symmetric shunt design indicated by 410b.

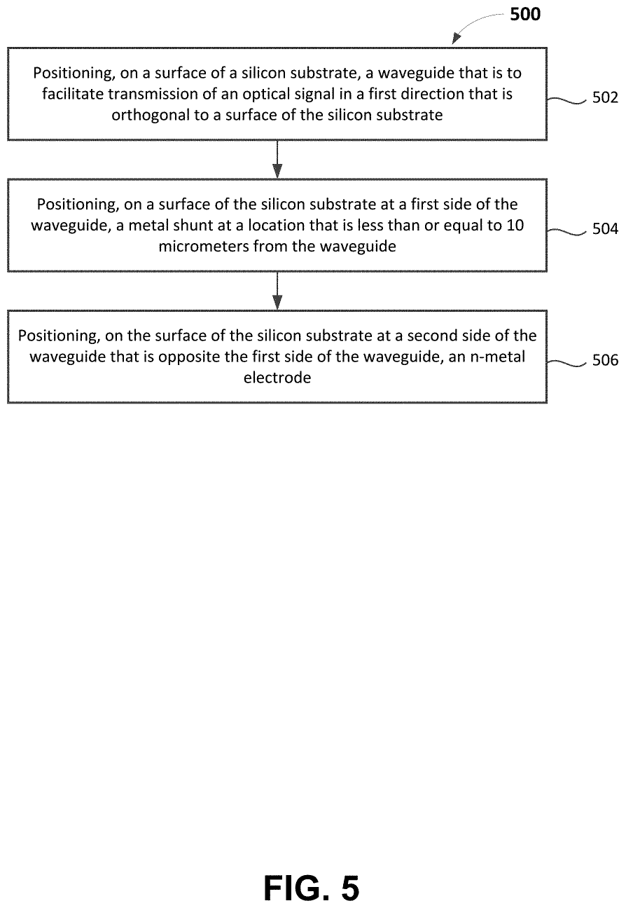

FIG. 5 illustrates an example process 500 related to forming a hybrid laser architecture with an asymmetric shunt, in accordance with various embodiments. The process 500 may be performed, for example, by the system 600 (e.g., computing device).

The process 500 may include positioning, at 502 on a surface of a silicon substrate, a waveguide that is to facilitate transmission of an optical signal in a first direction that is orthogonal to a surface of the silicon substrate. The silicon substrate may be similar to, for example silicon substrate layer 135. The waveguide may be similar to silicon waveguide 140. It will be noted that, in some embodiments, an intermediate layer (e.g., the SiO₂ layer 130) may be positioned between the waveguide and the surface of the silicon substrate.

The process 500 may further include positioning, at 504 on a surface of the silicon substrate at a first side of the waveguide (e.g., on the right side of waveguide 140 as oriented in FIG. 1), a metal shunt. The metal shunt may be similar to, for example metal shunt 145. The metal shunt may be positioned within (i.e., less than or equal to) a distance L2 (e.g., 10 microns) from the waveguide and, more specifically, with a distance L2 from a center of the waveguide.

The process 500 may further include positioning, at 506 on the surface of the silicon substrate at a second side of the waveguide that is opposite the first side of the waveguide (e.g., the left side of the waveguide 140 as oriented in FIG. 1), an n-metal electrode. The n-metal electrode may be similar to, for example, the n-metal electrode 120.

It should be understood that the actions described in reference to FIG. 5 may not necessarily occur in the described sequence. For example, certain elements may occur in an order different than that described, concurrently with one another, etc. In some embodiments, the process 500 may include more or fewer elements than depicted or described.

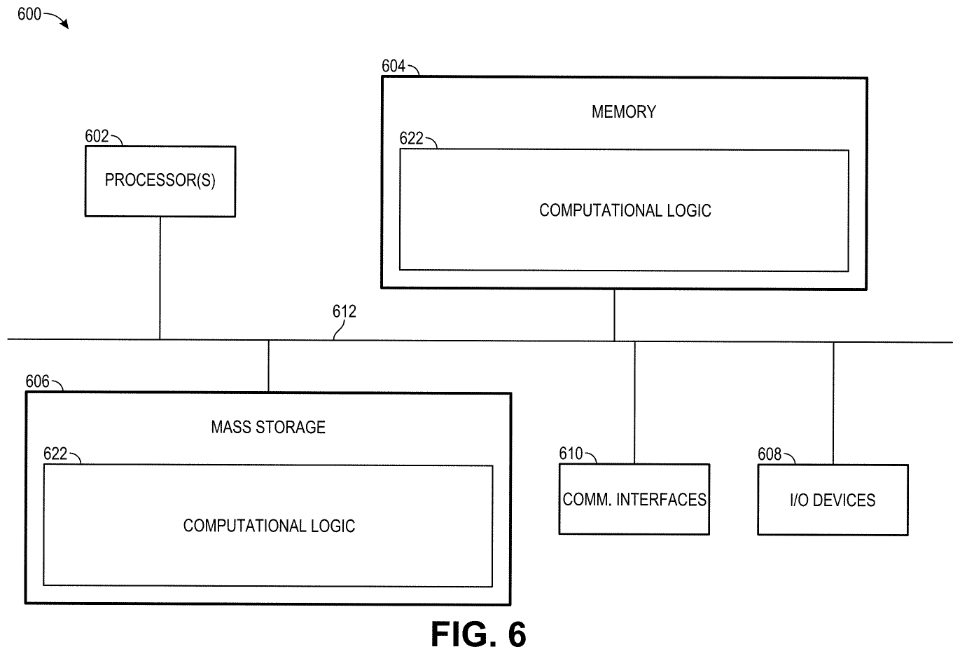

FIG. 6 illustrates an example computing device 600 suitable for use to practice aspects of the present disclosure, in accordance with various embodiments. For example, the example computing device 600 may be suitable to implement the functionalities, methods, techniques, or processes, in whole or in part, associated with any of FIGS. 1-5 and, more specifically, the manufacture of the various structures depicted in any of FIG. 1 or 2.

As shown, computing device 600 may include one or more processors 602, each having one or more processor cores, and system memory 604. The processor 602 may include any type of unicore or multi-core processors. Each processor core may include a central processing unit (CPU), and one or more level of caches. The processor 602 may be implemented as an integrated circuit. The computing device 600 may include mass storage devices 606 (such as diskette, hard drive, volatile memory (e.g., dynamic random access memory (DRAM)), compact disc read only memory (CD-ROM), digital versatile disk (DVD) and so forth). In general, system memory 604 and/or mass storage devices 606 may be temporal and/or persistent storage of any type, including, but not limited to, volatile and non-volatile memory, optical, magnetic, and/or solid state mass storage, and so forth. Volatile memory may include, but not be limited to, static and/or dynamic random access memory. Non-volatile memory may include, but not be limited to, electrically erasable programmable read only memory, phase change memory, resistive memory, and so forth.

The computing device 600 may further include input/output (I/O) devices 608 such as a display, keyboard, cursor control, remote control, gaming controller, image capture device, one or more three-dimensional cameras used to capture images, and so forth, and communication interfaces 610 (such as network interface cards, modems, infrared receivers, radio receivers (e.g., Bluetooth), and so forth). I/O devices 608 may be suitable for communicative connections with three-dimensional cameras or user devices. In some embodiments, I/O devices 608 when used as user devices may include a device necessary for implementing the functionalities of receiving an image captured by a camera.

The communication interfaces 610 may include communication chips (not shown) that may be configured to operate the device 600 in accordance with a Global System for Mobile Communication (GSM), General Packet Radio Service (GPRS), Universal Mobile Telecommunications System (UMTS), High Speed Packet Access (HSPA), Evolved HSPA (E-HSPA), or Long Term Evolution (LTE) network. The communication chips may also be configured to operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chips may be configured to operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication interfaces 610 may operate in accordance with other wireless protocols in other embodiments.

The above-described computing device 600 elements may be coupled to each other via system bus 612, which may represent one or more buses. In the case of multiple buses, they may be bridged by one or more bus bridges (not shown). Each of these elements may perform its conventional functions known in the art. In particular, system memory 604 and mass storage devices 606 may be employed to store a working copy and a permanent copy of the programming instructions implementing the operations, functionalities, techniques, methods, or processes, in whole or in part, associated with any of FIGS. 1-5 and/or the manufacture of the various structures depicted therein, generally shown as computational logic 622. Computational logic 622 may be implemented by assembler instructions supported by processor(s) 602 or high-level languages that may be compiled into such instructions.

The permanent copy of the programming instructions may be placed into mass storage devices 606 in the factory, or in the field, though, for example, a distribution medium (not shown), such as a compact disc (CD), or through communication interfaces 610 (from a distribution server (not shown)).

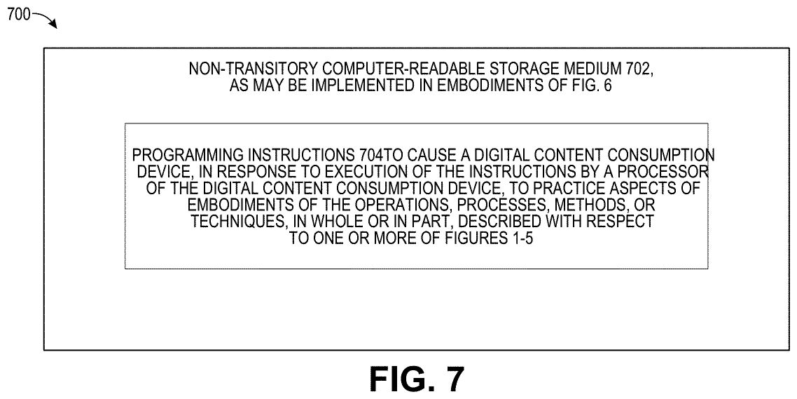

FIG. 7 illustrates an example non-transitory computer-readable storage media 702 having instructions configured to practice all or selected ones of the operations associated with the processes described above. As illustrated, non-transitory computer-readable storage medium 702 may include a number of programming instructions 704. Programming instructions 704 may be configured to enable a device, e.g., computing device 600, in response to execution of the programming instructions, to perform one or more operations, processes, methods, or techniques, in whole or in part, described in reference to any of FIGS. 1-5 and/or the manufacture of the various structures depicted in any of FIG. 1 or 2. In alternate embodiments, programming instructions 704 may be disposed on multiple non-transitory computer-readable storage media 702 instead. In still other embodiments, programming instructions 704 may be encoded in transitory computer-readable signals.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

### EXAMPLES

Example 1 includes an apparatus for use in a hybrid laser, wherein the apparatus comprises: a silicon substrate; a waveguide to facilitate transmission of an optical signal in a first direction that is orthogonal to a surface of the silicon substrate; and a metal shunt that is less than or equal to 10 micrometers from the waveguide in a second direction that is orthogonal to the surface of the silicon substrate and orthogonal to the first direction.

Example 2 includes the apparatus of example 1, and/or some other example herein, wherein the metal shunt includes aluminum.

Example 3 includes the apparatus of any of examples 1-2, and/or some other example herein, wherein the apparatus further comprises an n-metal electrode at a portion of the apparatus that is opposite the waveguide from the metal shunt.

Example 4 includes the apparatus of any of examples 1-3, and/or some other example herein, wherein the metal shunt is a heatsink.

Example 5 includes the apparatus of any of examples 1-4, and/or some other example herein, wherein the waveguide includes a silicon waveguide layer positioned on the silicon substrate, and a mesa positioned on the silicon waveguide layer.

Example 6 includes the apparatus of example 5, and/or some other example herein, wherein the mesa includes indium phosphate (InP).

Example 7 includes the apparatus of any of examples 1-6, and/or some other example herein, wherein the hybrid laser is a III-V hybrid laser.

Example 8 includes a method comprising: positioning, on a surface of a silicon substrate, a waveguide that is to facilitate transmission of an optical signal in a first direction that is orthogonal to a surface of the silicon substrate; and positioning, on a surface of the silicon substrate at a first side of the waveguide, a metal shunt at a location that is less than or equal to 10 micrometers from the waveguide; and positioning, on the surface of the silicon substrate at a second side of the waveguide that is opposite the first side of the waveguide, an n-metal electrode.

Example 9 includes the method of example 8, and/or some other example herein, wherein the metal shunt includes aluminum.

Example 10 includes the method of any of examples 8-9, and/or some other example herein, wherein the metal shunt is thermally coupled with, and draws heat from, the waveguide.

Example 11 includes the method of any of examples 8-10, and/or some other example herein, wherein the waveguide is a waveguide of a hybrid laser.

Example 12 includes the method of example 11, and/or some other example herein, wherein the hybrid laser is a III-V hybrid laser.

Example 13 includes the method of any of examples 8-12, and/or some other example herein, wherein the waveguide includes an indium phosphate (InP) mesa and a silicon waveguide layer.

Example 14 includes an electronic device comprising: a silicon substrate; a waveguide positioned on a surface of the silicon substrate, wherein the waveguide is to facilitate transmission of an optical signal in a first direction that is orthogonal to a surface of the silicon substrate; a metal shunt at a location that is less than or equal to 10 micrometers from the waveguide, wherein the metal shunt is on the surface of the silicon substrate at a first side of the waveguide; and an n-metal electrode on the surface of the silicon substrate at a second side of the waveguide that is opposite the first side of the waveguide.

Example 15 includes the electronic device of example 14, and/or some other example herein, wherein a second n-metal electrode is not positioned between the metal shunt and the waveguide.

Example 16 includes the electronic device of any of examples 14-15, and/or some other example herein, wherein the electronic device does not include a metal shunt on the surface of the silicon substrate at the second side of the waveguide.

Example 17 includes the electronic device of any of examples 14-16, and/or some other example herein, wherein the metal shunt includes aluminum.

Example 18 includes the electronic device of any of examples 14-17, wherein the metal shunt is thermally coupled with, and draws heat from, the waveguide.

Example 19 includes the electronic device of any of examples 14-18, wherein the waveguide includes a silicon waveguide layer positioned on the silicon substrate, and a mesa positioned on the silicon waveguide layer.

Example 20 includes electronic device of any of examples 14-19, and/or some other example herein, wherein the hybrid laser is a III-V hybrid laser.

Example Z01 may include an apparatus comprising means to perform one or more elements of a method described in or related to any of the examples herein, and/or any other method, process, or technique process described herein, or portions or parts thereof

Example Z02 may include an apparatus comprising logic, modules, or circuitry to perform one or more elements of a method described in or related to any of the examples herein, and/or any other method, process, or technique described herein, or portions or parts thereof

Example Z03 may include a method, technique, or process as described in or related to any of the examples herein, and/or any other method, process, or technique described herein, or portions or parts thereof.

Example Z04 may include a signal as described in or related to any of the examples herein, and/or any other method, process, or technique described herein, or portions or parts thereof.

Example Z05 may include an apparatus comprising one or more processors and non-transitory computer-readable media that include instructions which, when executed by the one or more processors, are to cause the apparatus to perform one or more elements of a method described in or related to any of the examples herein, and/or any other method, process, or technique described herein, or portions or parts thereof.

Example Z06 may include one or more non-transitory computer readable media comprising instructions that, upon execution of the instructions by one or more processors of an electronic device, are to cause the electronic device to perform one or more elements of a method described in or related to any of the examples herein, and/or any other method, process, or technique described herein, or portions or parts thereof.

Example Z07 may include a computer program related to one or more elements of a method described in or related to any of the examples herein, and/or any other method, process, or technique described herein, or portions or parts thereof.

1. An apparatus for use in a hybrid laser, wherein the apparatus comprises:
a silicon substrate;
a waveguide to facilitate transmission of an optical signal in a first direction that is orthogonal to a surface of the silicon substrate; and
a metal shunt that is less than or equal to 10 micrometers from the waveguide in a second direction that is orthogonal to the surface of the silicon substrate and orthogonal to the first direction.

2. The apparatus of claim 1, wherein the metal shunt includes aluminum.

3. The apparatus of claim 1, wherein the apparatus further comprises an n-metal electrode at a portion of the apparatus that is opposite the waveguide from the metal shunt.

4. The apparatus of claim 1, wherein the metal shunt is a heatsink.

5. The apparatus of claim 1, wherein the waveguide includes a silicon waveguide layer positioned on the silicon substrate, and a mesa positioned on the silicon waveguide layer.

6. The apparatus of claim 5, wherein the mesa includes indium phosphate (InP).

7. The apparatus of claim 1, wherein the hybrid laser is a III-V hybrid laser.

8. A method comprising:
positioning, on a surface of a silicon substrate, a waveguide that is to facilitate transmission of an optical signal in a first direction that is orthogonal to a surface of the silicon substrate; and
positioning, on a surface of the silicon substrate at a first side of the waveguide, a metal shunt at a location that is less than or equal to 10 micrometers from the waveguide; and
positioning, on the surface of the silicon substrate at a second side of the waveguide that is opposite the first side of the waveguide, an n-metal electrode.

9. The method of claim 8, wherein the metal shunt includes aluminum.

10. The method of claim 8, wherein the metal shunt is thermally coupled with, and draws heat from, the waveguide.

11. The method of claim 8, wherein the waveguide is a waveguide of a hybrid laser.

12. The method of claim 11, wherein the hybrid laser is a III-V hybrid laser.

13. The method of claim 8, wherein the waveguide includes an indium phosphate (InP) mesa and a silicon waveguide layer.

14. An electronic device comprising:
a silicon substrate;
a waveguide positioned on a surface of the silicon substrate, wherein the waveguide is to facilitate transmission of an optical signal in a first direction that is orthogonal to a surface of the silicon substrate;
a metal shunt at a location that is less than or equal to 10 micrometers from the waveguide, wherein the metal shunt is on the surface of the silicon substrate at a first side of the waveguide; and
an n-metal electrode on the surface of the silicon substrate at a second side of the waveguide that is opposite the first side of the waveguide.

15. The electronic device of claim 14, wherein a second n-metal electrode is not positioned between the metal shunt and the waveguide.

16. The electronic device of claim 14, wherein the electronic device does not include a metal shunt on the surface of the silicon substrate at the second side of the waveguide.

17. The electronic device of claim 14, wherein the metal shunt includes aluminum.

18. The electronic device of claim 14, wherein the metal shunt is thermally coupled with, and draws heat from, the waveguide.

19. The electronic device of claim 14, wherein the waveguide includes a silicon waveguide layer positioned on the silicon substrate, and a mesa positioned on the silicon waveguide layer.

20. The electronic device of claim 14, wherein the hybrid laser is a III-V hybrid laser.
